(19) United States
(12) Patent Application Publication
(10) Pub. No.: US 2021/0084795 A1
(43) Pub. Date: Mar. 18, 2021

(54) FLUID COOLED HEATSINK WITH FLOW CONTROL FOILS

(71) Applicant: SolidRun Ltd., Yokneam Illit (IL)

(72) Inventors: Atai ZIV, Matan (IL); Rabeeh KHOURY, Tarshisha (IL); Kossay OMARY, Nazareth (IL); Philip SHAHEEN, Ma'alot-Tarshiha (IL); Alon ROTMAN, Haifa (IL)

(73) Assignee: SolidRun Ltd., Yokneam Illit (IL)

(21) Appl. No.: 17/022,747

(22) Filed: Sep. 16, 2020

Related U.S. Application Data
(60) Provisional application No. 62/900,827, filed on Sep. 16, 2019.

(51) Int. Cl. H05K 7/20

(52) U.S. Cl. CPC H05K 7/20409; H05K 7/20245; H05K 7/20127

(57) ABSTRACT

An active fluid cooled heatsink is provided. The heatsink includes a heatsink body having a cavity therein, the heatsink body having at least a top internal surface and a bottom internal surface; at least an inlet for receiving fluid at a first temperature into the cavity; at least an outlet for expelling fluid at a second temperature from the cavity; a plurality of foils within the cavity, disposed in contact with the bottom internal surface of the heatsink body, where the plurality of foils direct the flow of the fluid; and a surface area on which to mount a plurality of resource adapters.

### CROSS-REFERENCE TO RELATED APPLICATIONS

This application claims the benefit of U.S. Provisional Application No. 62/900,827 filed on Sep. 16, 2019, the contents of which are hereby incorporated by reference.

### TECHNICAL FIELD

The disclosure relates generally to fluid cooled heatsinks and particularly to heat dissipating fins.

### BACKGROUND

While heat exchangers and heatsinks are known in the field of thermal management, existing solutions fail to provide for adaptability to modular systems, particularly systems with high exchange efficiency requirements, exchange-fluid limitations, and package footprint limitations. Existing heat exchangers and heatsinks may fail to provide for optimization of thermal management considerations including exchange fluid selection, fin shape, placement, and orientation, and exchange fluid flow regulation. Further, existing heat exchangers and sinks may fail to provide optimal exchange efficiency based on optimization of those factors listed.

In addition, existing solutions may lack refinements which provide for use of high-efficiency exchange fluids in configurations where such fluids are in direct contact with electronic devices, limiting the applicability of existing solutions to those cases wherein a device must be isolated from an exchange fluid, and wherein the selection of an exchange fluid is limited by device sensitivity. Existing solutions may also lack package configurations designed to provide for low-footprint implementation in server settings, in which settings package footprint or volume may limit device applicability. Further, existing solutions may fail to provide for optimization of those factors described above, in combination.

It would be, therefore, advantageous to provide solution that would overcome the deficiencies mentioned above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “certain embodiments” may be used herein to refer to a single embodiment or multiple embodiments of the disclosure.

Certain embodiments disclosed herein include an active fluid cooled heatsink. The disclosed heatsink includes a heatsink body having a cavity therein, the heatsink body having at least a top internal surface and a bottom internal surface; at least an inlet for receiving fluid at a first temperature into the cavity; at least an outlet for expelling fluid at a second temperature from the cavity; a plurality of foils within the cavity, disposed in contact with the bottom internal surface of the heatsink body, where the plurality of foils direct the flow of the fluid; and a surface area on which to mount a plurality of resource adapters.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a schematic illustration of a side view of a fluid cooled heatsink unit coupled with a plurality of server rack resources, implemented in accordance with an embodiment.

FIG. 2A is a schematic illustration of a top cross section view of a fluid cooled heatsink unit, implemented in accordance with an embodiment.

FIG. 2B is a schematic illustration of an isometric top front view of the fluid cooled heatsink unit.

FIG. 3 is a schematic illustration of a top cross section view of a fluid cooled heatsink unit coupled with a plurality of server rack resources, implemented in accordance with another embodiment.

### DETAILED DESCRIPTION

The embodiments disclosed by the invention are only examples of the many possible advantageous uses and implementations of the innovative teachings presented herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

According to some example embodiments a novel heatsink is provided. The heatsink includes a cavity into which a fluid may enter at a first temperature and exit at a higher temperature, having exchanged heat with one or more electronic resources coupled thereto. The cavity includes a plurality of foils, which serve to control the flow of the fluid. Fins, dividers, channels, stops, and combinations thereof may be used in different embodiments. Each electronic resource is fitted with a resource adapter which has a first geometry which is unique to the electronic resource, and a second geometry which ensures maximum contact with a surface of the heatsink. This approach provides for connecting modular resources to the heatsink and coupling them with a controller which allows client devices to access the electronic resources.

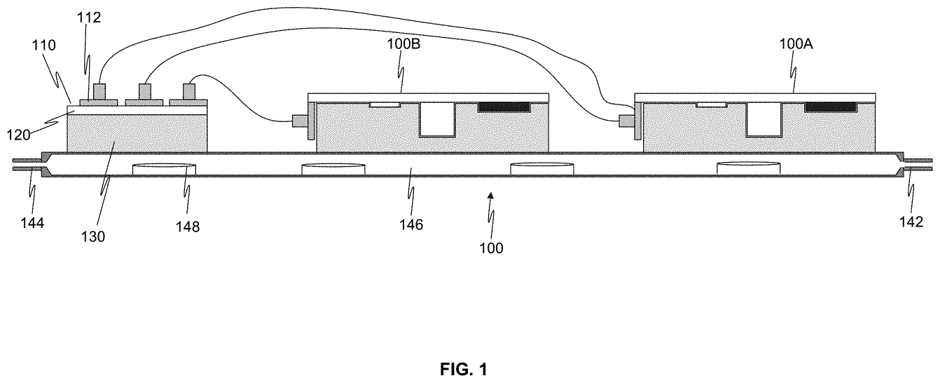

FIG. 1 is a schematic illustration of a side view of a fluid cooled heatsink unit coupled with a plurality of server rack resources, implemented in accordance with an embodiment. A fluid cooled heatsink 100 includes an inlet 142 for allowing fluid at a first temperature to enter a chamber 146 of the heatsink 100, and an outlet 144 for allowing the fluid to exit at a second temperature, which is higher than the first temperature, due to absorbing heat from at least one resource, such as resource 100A. In an embodiment, the heatsink 100 may include one or more inlets and one or more outlets. Heat therefore flows from the resource (or components of the resource which generate heat), to the heatsink adapter, to the heatsink, where it is extracted via heat exchange with the fluid. The fluid may be, as examples and without limitation, a cooled gas, a liquid, an engineered fluid, and the like, as well as any combination thereof.

An engineered fluid may be adapted, for example, with high dielectric performance, providing for contact with electronic components without damaging such components, including, as an example and without limitation, such fluids as perfluorocarbons (PFCs). The fluid is dissipated through the chamber by way of fins 148 (also referred to herein as “foils”), so as to decrease heat gradients. In the absence of fins, heat gradients may occur. Heat gradients occur if the temperature of the liquid entering the chamber increases rapidly, causing a reduction in the efficacy of heat exchange via the liquid flowing through the chamber. The presence of fluid-directing fins, which cause the liquid to flow around a larger surface area of the chamber, may reduce heat gradients and increase efficacy of heat exchange.

The fins 148 are located on the bottom surface of the heat sink chamber. The fins 148 may have a height ranging from several microns to the height of the top surface of the chamber. Top and bottom are understood to be relative terms and, in this example, the bottom surface is the surface at which the fins 148 are located, while the top surface is a surface of the heatsink opposite the bottom surface. The fluid may exit the chamber 146 through the outlet into another heat exchange, where the fluid is relieved of at least some excess heat and, then, recycled back into the inlet 142 to repeat the process. The adapter allows manufacturing of a heatsink with a geometry which provides for connection to a maximum number of resources, while dissipating a large amount of heat generated by those resources. In this illustrative embodiment, the heatsink has a flat (top) surface which is parallel to the flat surface of the heatsink adapter.

However, it should be readily understood that, in other embodiments, different geometries may be used, including, for example and without limitation, geometries which provide the adapter a larger surface area connection to the heatsink, or geometries which provide for fastening the adapter to the heatsink 100. In some embodiments, a thermally conductive compound such as thermal grease may be used between the resource and the adapter, and between the adapter and the heatsink 100. The thermally conductive compound may be electrically insulating, or in some embodiments, electrically conducting. The compound may be used to eliminate any gaps between the heat exchanges, as any lack of contact (i.e. air between the surfaces) is not thermally conductive and would, therefore, lead to reduced heat dissipation.

It should be appreciated that use of the adapter also provides for a modular approach to constructing server racks or blades. While prior art solutions usually rely on some set configuration of blade or rack, the proposed solution can implement more dynamic requirements. For example, if, typically, a group of processors takes up an entire rack or blade unit, but the application does not require such an amount of processors, then, by implementing the proposed solution, the space used by the redundant processors may be used for other components, such as storage, memory, GPUs, and the like. The heatsink unit 100 is further coupled with a management module 110, which includes a heatsink adapter 330, and a substrate 120, on which substrate 120 a plurality of connectors (such as connector 112) may be implemented, providing for communication between the management module 110 and the resources, such as resource 100B.

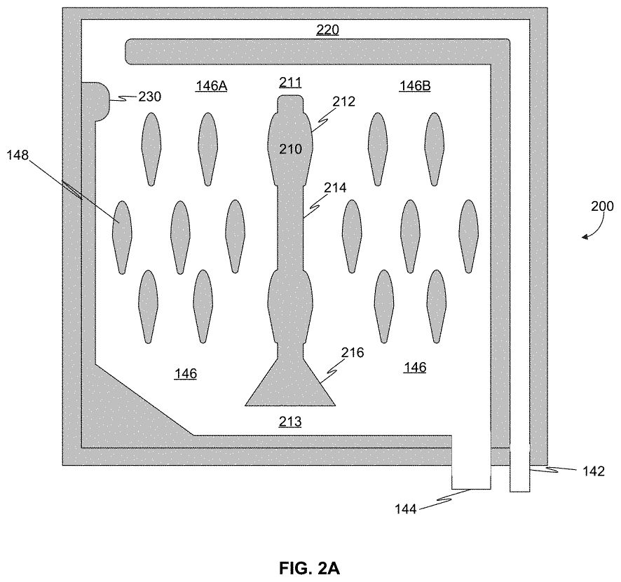

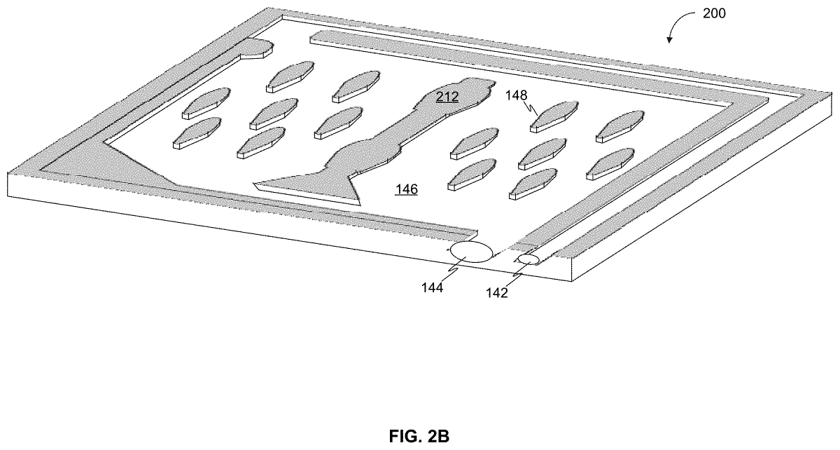

FIG. 2A is a schematic illustration of a top cross-section view of a fluid cooled heatsink unit, implemented in accordance with an embodiment. FIG. 2B is a schematic illustration of an isometric top front view of the fluid cooled heatsink unit. The heatsink 200 includes an inlet 142 which allows fluid to enter a channel 220. In an embodiment, the heatsink 220 may include a plurality of inlets. The channel 220 regulates the flow of fluid from the inlet into a chamber 146. In some embodiments, the channel may taper to increase or reduce the pressure at which fluid enters the chamber 146.

In some examples, the channel 220 culminates in a stop 230. The stop 230 disrupts flow of the fluid, causing turbulence to occur. The turbulence may ensure that the fluid is spread between chamber regions 146A and 146B. The chamber 146 may be split into two or more subsections (such as right subsection 146A and left subsection 146B) by a divider 210. The subsections may be connected by at least two channels, including one channel through which fluid flows into the subsection, and another channel through which fluid exits the subsection. In this example, channel 211, connected subsections 146A and 146B, where fluid enters, and channel 213, connect to the subsections where the fluid exits. The divider may taper out, such as in divider section 212 or section 216, or taper in, such as in divider section 214. The fins 148, stop 230, and divider(s) 210 control the flow of fluid and may be utilized in different configurations to achieve different heat exchange results. Fins, dividers, channels, stops, and combinations thereof may be used in various embodiments. In some embodiments the fins, dividers, and stops may all be the same height. In certain embodiments, a portion of the fins can be at one height, a second portion at another height, and the like. In additional embodiments, fins, dividers, and stops, may each be at a different height.

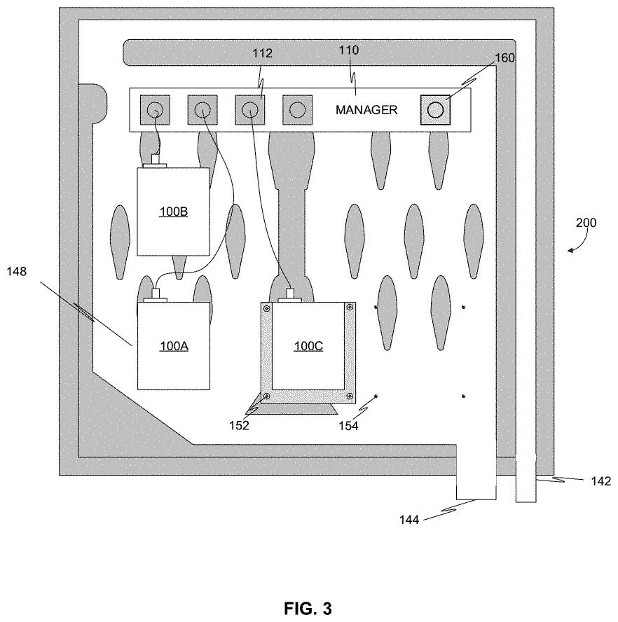

FIG. 3 is a schematic illustration of a top cross section view of a fluid cooled heatsink unit coupled with a plurality of server rack resources, implemented in accordance with another embodiment. The fluid cooled heatsink unit is shown from a top cross-section, with images of resources and management module superimposed above. The heatsink 200 is coupled with a plurality of resources, 100A, 1006, and 100C, each of which is connected to a management module (manager) 110. The heatsink adapters of resources 100A and 100B have a smaller area than the substrate of their respective resources, while the heatsink adapter of resource 100C is larger than its substrate. Having a heatsink adapter with an area larger than an area of the resource may allow, for example, for mechanical coupling of the heatsink adapter to the heatsink 100. This may be done by a mechanical fastener, such as a screw 152 or bolt.

A fastener may be affixed through a hole or perforation such as hole 154, which may or may not be threaded, depending on the type of mechanical fastener used. It should be noted that, though the terms ‘hole’ and ‘perforation’ are used, it is not always advantageous to have a hole bore through the entire thickness of the heatsink, as this would either allow fluid to extrude from the hole, or more likely, to be defined by a solid area of the heatsink through which liquid does not flow, thereby hindering its ability to expel heat. It may, therefore, be more useful to have fastener holes whose depths are such that they do not perforate the chamber through which fluid is flowing. EPMs (electro-permanent magnets) may be used as a fastening device, replacing screws 152. The manager 110 further includes a power supply 160 which is operative to connect to a power grid and to supply the manager 110 and resources with electric power.

In an embodiment, the resources may connect directly to the power supply while, in other embodiments, the resources are provided power through a cable which connects the resource with the manager 110. The top surface of the heatsink 200 is not shown in this view to better aid in visualizing the resources mounted to the heatsink 200. However, it should be understood that the top surface is present in this disclosure.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

What is claimed is:

1. An active fluid cooled heatsink comprising:
a heatsink body having a cavity therein, the heatsink body having at least a top internal surface and a bottom internal surface;
at least an inlet for receiving fluid at a first temperature into the cavity;
at least an outlet for expelling fluid at a second temperature from the cavity;
a plurality of foils within the cavity, disposed in contact with the bottom internal surface of the heatsink body, where the plurality of foils direct the flow of the fluid; and
a surface area on which to mount a plurality of resource adapters.

2. The heatsink of claim 1, wherein the heatsink further comprises:
a plurality of inlets.

3. The heatsink of claim 1, wherein the second temperature is higher than the first temperature.

4. The heatsink of claim 1, wherein the fluid is at least any one of: a cooled gas, a liquid, and an engineered fluid.

5. The heatsink of claim 4, wherein an engineered fluid is a fluid having high dielectric performance.

6. The heatsink of claim 1, further comprising:
at least a channel for directing flow of the fluid.

7. The heatsink of claim 6, wherein the channel is tapered to provide at least one of: a reduction in fluid pressure, and an increase in fluid pressure.

8. The heatsink of claim 1, further comprising:
a plurality of resource adapters wherein the resource adapters are operative for exchanging heat from a corresponding electronic resource to the fluid cooled heatsink.

9. The heatsink of claim 8, further comprising:
a thermally-conductive compound disposed at least one of: an interface between the electronic resource and the corresponding resource adapter, and an interface between the heatsink and a resource adapter.

10. The heatsink of claim 9, wherein the thermally-conductive compound is at least one of: electrically-conductive, and electrically-insulating

11. The heatsink of claim 8, wherein each resource adapter comprises:
a first surface having a geometric shape which conforms to the corresponding electronic resource; and
a second surface having a geometric shape corresponding to at least a portion of the surface area of the heatsink.

12. The heatsink of claim 11, wherein the second surface has a geometric shape providing maximized contact surface area with the portion of the surface area of the heatsink.

13. The heatsink of claim 11, wherein the second surface has a geometric shape providing for fastening of the resource adapter to the heatsink

14. The heatsink of claim 1, further comprising:
a controller.

15. The heatsink of claim 14, wherein the controller further comprises:
an I/O interface, wherein the I/O interface is adapted to connect to a plurality of electronic resources; and
a power supply, wherein the power supply is operative for at least one of: connecting the controller to a power grid and supplying power from the power grid to the controller.

16. The heatsink of claim 15, wherein the plurality of resources are powered by at least one of: direct connection to the power supply, and connection to the controller.

17. The heatsink of claim 1, further comprising:
a divider within the cavity, wherein the divider defines at least two cavity portions, and wherein the at least two cavity portions are connected by a channel.

18. The heatsink of claim 17 wherein the divider and the plurality of foils are at least any one of: equal in height, and unequal in height

19. The heatsink of claim 1, further comprising:
a turbulence-inducing stop.

20. The heatsink of claim 19, wherein the stop and the plurality of foils are at least one of: equal in height, and unequal in height
